(19) United States
(12) Patent Application Publication
(10) Pub. No.: US 2025/0329614 A1
(43) Pub. Date: Oct. 23, 2025

(54) SEMICONDUCTOR DEVICE AND METHOD FOR MANUFACTURING THE SAME

(71) Applicant: Samsung Electronics Co., Ltd., Suwon-si (KR)

(72) Inventors: Jang Ho Kim, Suwon-si (KR); Sang Ki Kim, Suwon-si (KR); Cheol Myung Kim, Suwon-si (KR); Ki Wook Sung, Suwon-si (KR)

(21) Appl. No.: 18/910,395

(22) Filed: Oct. 9, 2024

(30) Foreign Application Priority Data
Apr. 17, 2024 (KR) 10-2024-0051479

(51) Int. Cl. H01L 23/48; H01L 21/768; H01L 25/065; H01L 25/18; H10B 80/00

(52) U.S. Cl. CPC H01L 23/481; H01L 21/76898; H01L 25/0657; H01L 25/18; H10B 80/00; H01L 2225/06513; H01L 2225/06541

(57) ABSTRACT

A semiconductor device includes: a substrate; a first interlayer insulating film on the substrate; a through-via extending through the substrate and the first interlayer insulating film; a second interlayer insulating film on the first interlayer insulating film, wherein the second interlayer insulating film includes a low dielectric constant material and is in contact with an upper surface of the first interlayer insulating film; and a first wiring pattern in the second interlayer insulating film and on the through-via.

### CROSS-REFERENCE TO RELATED APPLICATION

This application claims priority from Korean Patent Application No. 10-2024-0051479 filed on Apr. 17, 2024, in the Korean Intellectual Property Office, and all the benefits accruing therefrom under 35 U.S.C. § 119, the contents of which in its entirety are herein incorporated by reference.

### BACKGROUND

The present disclosure relates generally to a semiconductor device and a method for manufacturing the semiconductor device.

In accordance with the rapid development of the electronics industry and user demands, electronic devices are becoming more compact and multi-functional. Therefore, high integration of a semiconductor chip used in the electronic devices is required, such that the design rule for components of the semiconductor chip is decreasing. Accordingly, there is a need for a method of introducing a low dielectric constant insulating layer to reduce parasitic capacitance inside the semiconductor chip, especially between wirings.

### SUMMARY

A technical purpose that the present disclosure seeks to achieve is to provide a semiconductor device with improved product reliability. The inventive concept, as manifested in one or more embodiments, provides a semiconductor package in which a plurality of semiconductor chips with through silicon vias (TSV) are stacked in a vertical direction.

Another technical purpose that the present disclosure seeks to achieve is to provide a method for manufacturing a semiconductor device that may result in a semiconductor device with improved product reliability.

Embodiments according to the present disclosure are not limited to the above-mentioned purpose(s). Other purposes and advantages according to the present disclosure that are not mentioned may be understood based on the following descriptions, and may be more clearly understood based on embodiments according to the present disclosure. Further, it will be easily understood that the purposes and advantages according to the present disclosure may be realized using means shown in the claims or combinations thereof.

According to an example embodiment of the present disclosure, a semiconductor device includes: a substrate; a first interlayer insulating film on the substrate; a through-via extending through the substrate and the first interlayer insulating film; a second interlayer insulating film on the first interlayer insulating film, wherein the second interlayer insulating film includes a low dielectric constant material and is in contact with an upper surface of the first interlayer insulating film; and a first wiring pattern in the second interlayer insulating film and on the through-via.

According to an example embodiment of the present disclosure, a semiconductor device includes: a substrate; a circuit element on the substrate; a contact on the substrate and electrically connected to the circuit element; a first interlayer insulating film on the substrate so as to cover the circuit element and the contact; a through-via extending through the first interlayer insulating film and the substrate; a second interlayer insulating film on the first interlayer insulating film, wherein the second interlayer insulating film includes a low dielectric constant material and non-contacts the through-via; a first wiring pattern extending through the second interlayer insulating film so as to contact the through-via; and a second wiring pattern extending through the second interlayer insulating film so as to contact the contact.

According to an example embodiment of the present disclosure, a method for manufacturing a semiconductor device includes: forming a first interlayer insulating film on a substrate, and forming a contact in the first interlayer insulating film; forming a pre-through-via extending through a portion of the substrate and the first interlayer insulating film; forming a first etch stop film on the pre-through-via such that the first etch stop film does not cover the first interlayer insulating film so as to be exposed in an area in which the contact is formed; forming a second interlayer insulating film on the first etch stop film and the first interlayer insulating film; forming a first wiring trench and a second wiring trench in the second interlayer insulating film, wherein the forming of the first wiring trench includes etching the second interlayer insulating film and the first etch stop film, wherein the forming of the second wiring trench includes etching the second interlayer insulating film; and forming a first wiring pattern filling the first wiring trench and a second wiring pattern filling the second wiring trench. The term “filling” (or “fill,” or like terms), as may be used herein, is intended to refer broadly to either completely filling a defined space (e.g., the first wiring trench) or partially filling the defined space; that is, the defined space need not be entirely filled but may, for example, be partially filled or have voids or other spaces throughout.

### BRIEF DESCRIPTION OF DRAWINGS

The above and other aspects and features of the present disclosure will become more apparent by describing in detail some embodiments thereof with reference to the attached drawings, wherein like reference numerals (when used) indicate corresponding elements throughout the several views, and in which:

FIG. 1 is a schematic cross-sectional view illustrating a semiconductor device according to some embodiments;

FIG. 2 is an enlarged view of a portion A of the semiconductor device shown in FIG. 1;

FIG. 3 and FIG. 4 are enlarged views of a portion B of the semiconductor device shown in FIG. 1;

FIG. 5 and FIG. 6 are enlarged views of the portion A of the semiconductor device shown in FIG. 1;

FIGS. 7 to 15 are schematic cross-sectional views illustrating intermediate processes in an example method for manufacturing a semiconductor device according to some embodiments;

FIG. 16 is a schematic side view illustrating an example semiconductor package according to some embodiments;

FIG. 17 is a schematic perspective view illustrating an implementation example of a semiconductor package according to some embodiments;

FIG. 18 is a schematic cross-sectional view illustrating a semiconductor package according to some embodiments; and

FIG. 19 is a schematic perspective view illustrating a memory device according to some embodiments.

### DETAILED DESCRIPTION

Although terms such as first, second, upper, and lower are used herein to describe various elements or components, these elements or components are not limited by such terms. Rather, the terms are merely used herein to distinguish one element or component from another element or component. Therefore, a first element or component as mentioned below may also be referred to as a second element or component within the technical spirit of the present disclosure. Further, a lower element or component as mentioned below may also be referred to as an upper element or component within the technical spirit of the present disclosure.

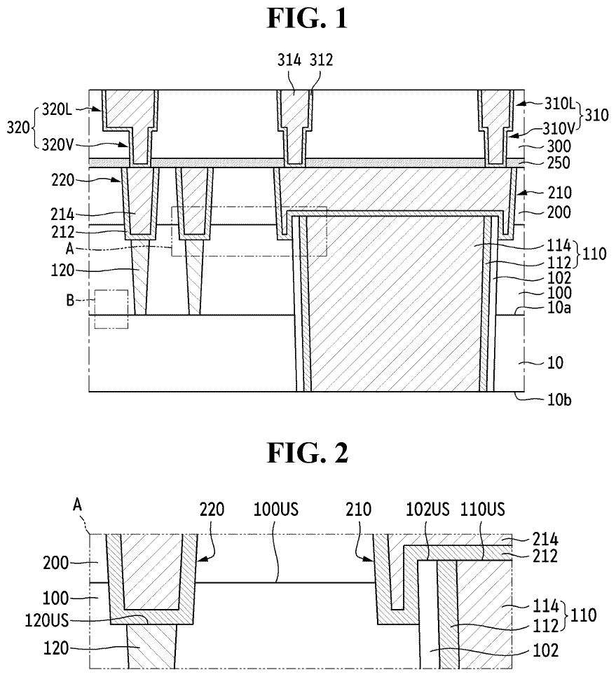

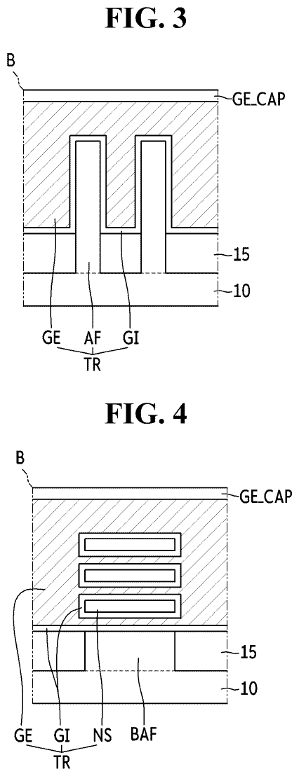

FIG. 1 is a schematic cross-sectional view illustrating a semiconductor device according to some embodiments. FIG. 2 is an enlarged view of a portion A of the semiconductor device shown in FIG. 1. FIG. 3 and FIG. 4 are enlarged views of a portion B of the semiconductor device shown in FIG. 1.

Referring to FIGS. 1 to 4, a semiconductor device according to some embodiments may include a substrate 10, a first interlayer insulating film 100, a via insulating layer 102, a through-via 110, a contact 120, a second interlayer insulating film 200, a first lower wiring pattern 210, a second lower wiring pattern 220, a third interlayer insulating film 300, a first upper wiring pattern 310, and a second upper wiring pattern 320.

The substrate 10 may include a first surface 10a and a second surface 10b which are opposite to each other in a vertical direction perpendicular to an upper surface of the substrate 10. The substrate 10 may be a silicon substrate or SOI (silicon-on-insulator). Alternatively, the substrate 10 may include a material other than silicon, such as silicon germanium, silicon germanium on insulator (SGOI), indium antimonide, lead telluride compound, indium arsenide, indium phosphide, gallium arsenide or gallium antimonide. However, embodiments of the present disclosure are not limited thereto. Hereinafter, an upper surface, a lower surface, upper, lower, on top of, under, and a bottom surface are defined based on a direction from the second surface 10b to the first surface 10a.

The first interlayer insulating film 100 may be disposed on the first surface 10a of the substrate 10. The first interlayer insulating film 100 may include, for example, tetraethyl orthosilicate (TEOS).

The contact 120 may be disposed on the first surface 10a of the substrate 10. The contact 120 may be disposed within the first interlayer insulating film 100. For example, contact 120 may include at least one of aluminum (Al), copper (Cu), tungsten (W), cobalt (Co), ruthenium (Ru), silver (Ag), gold (Au), manganese (Mn), and molybdenum (Mo).

A circuit element may be disposed on the first surface 10a of the substrate 10. The circuit element may be electrically connected to the contact 120. The circuit element may include a transistor TR. The term “connected” (or “connecting,” or like terms, such as “contact” or “contacting”), as may be used herein, is intended to refer to a physical and/or electrical connection between two or more elements, and may include other intervening elements. As used herein, the term “and/or” includes any and all combinations of one or more of the associated listed items.

Referring to FIG. 3, in some embodiments, the transistor TR may include a fin-type pattern AF, a gate electrode GE disposed on the fin-type pattern AF, and a gate insulating film GI between the fin-type pattern AF and the gate electrode GE. Although not shown, the transistor TR may include source/drain patterns respectively disposed on both opposing sides of the gate electrode GE.

The fin-type pattern AF may protrude from the substrate 10 (e.g., extending upwardly from the first surface 10a of the substrate 10 in the vertical direction). The fin-type pattern AF may extend in one direction. The fin-type pattern AF may be a portion of the substrate 10 or may include an epitaxial layer grown from the substrate 10. The fin-type pattern AF may include, for example, silicon or germanium which is an elemental semiconductor material. Furthermore, the fin-type pattern AF may include a compound semiconductor, for example, a group IV-IV compound semiconductor or a group III-V compound semiconductor.

The group IV-IV compound semiconductor may include, for example, a binary compound including two of carbon (C), silicon (Si), germanium (Ge), and tin (Sn), a ternary compound including three thereof, or a compound obtained by doping a group IV element thereto. The group III-V compound semiconductor may include, for example, a binary compound obtained by combining one of aluminum (Al), gallium (Ga), and indium (In) as a group III element and one of phosphorus (P), arsenic (As), and antimony (Sb) as a group V element with each other, a ternary compound obtained by combining two of aluminum (Al), gallium (Ga), and indium (In) as a group III element and one of phosphorus (P), arsenic (As), and antimony (Sb) as a group V with each other, or a quaternary compound obtained by combining three of aluminum (Al), gallium (Ga), and indium (In) as a group III element and one of phosphorus (P), arsenic (As), and antimony (Sb) as a group V with each other.

A field insulating film 15 may be disposed on the substrate 10. The field insulating film 15 may be formed on a portion of a sidewall of the fin-type pattern AF. The fin-type pattern AF may protrude upwardly beyond an upper surface of the field insulating film 15. The field insulating film 15 may include, for example, an oxide film, a nitride film, an oxynitride film, or a combination film thereof, although embodiments are not limited thereto.

The gate electrode GE may be disposed on the fin-type pattern AF. The gate electrode GE may extend in the other direction that intersects one direction from which the fin-type pattern AF extends. The gate electrode GE may intersect with the fin-type pattern AF.

For example, the gate electrode GE may include at least one of metal, conductive metal nitride, conductive metal carbonitride, conductive metal carbide, metal silicide, doped semiconductor material, conductive metal oxynitride, and/or conductive metal oxide.

The gate insulating film GI may be disposed between the gate electrode GE and the fin-type pattern AF, and between the gate electrode GE and the field insulating film 15. The gate insulating film GI may be conformally formed on an upper portion of the fin-type pattern AF. The term “conformally” (or “conformal,” or like terms), as may be used herein in the context of a material layer or coating, is intended to refer broadly to a material layer or coating having a substantially uniform cross-sectional thickness relative to the contour of a surface to which the material layer is applied. The term “cover” (or “covers” or “covering,” or like terms), as may be used herein, is intended to broadly refer to a material, layer or structure being on or over another material, layer or structure, but does not require the material, layer or structure to entirely cover the other material, layer or structure. The gate insulating film GI may include, for example, silicon oxide, silicon oxynitride, silicon nitride, or a high dielectric constant material with a higher dielectric constant than that of silicon oxide. The high dielectric constant material may include, for example, at least one of boron nitride, metal oxide, and metal silicon oxide.

The semiconductor device according to some embodiments may include an NC (negative capacitance) FET using a negative capacitor. For example, the gate insulating film GI may include a ferroelectric material film having ferroelectric properties and a paraelectric material film having paraelectric properties.

The ferroelectric material film may have negative capacitance, and the paraelectric material film may have positive capacitance. For example, when two or more capacitors may be connected in series to each other, and capacitance of each of the capacitors has a positive value, a total capacitance is smaller than capacitance of each individual capacitor. On the contrary, when at least one of capacitances of two or more capacitors connected in series to each other has a negative value, a total capacitance may have a positive value and be greater than an absolute value of each individual capacitance.

When the ferroelectric material film with negative capacitance and the paraelectric material film with positive capacitance are connected in series to each other, a total capacitance value of the ferroelectric material film and the paraelectric material film connected in series to each other may be increased. Using the increase in the total capacitance value, a transistor including the ferroelectric material film may have a subthreshold swing (SS) lower than about 60 mV/decade at room temperature.

The ferroelectric material film may have ferroelectric properties. The ferroelectric material film may include, for example, at least one of hafnium oxide, hafnium zirconium oxide, barium strontium titanium oxide, barium titanium oxide, and/or lead zirconium titanium oxide, although embodiments are not limited thereto. In this connection, in one example, hafnium zirconium oxide may refer to a material obtain by doping hafnium oxide with zirconium (Zr). In another example, hafnium zirconium oxide may refer to a compound of hafnium (Hf), zirconium (Zr), and oxygen (O).

The ferroelectric material film may further contain doped dopants. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr) and tin (Sn). A type of the dopant contained in the ferroelectric material film may vary depending on a type of the ferroelectric material included in the ferroelectric material film.

When the ferroelectric material film includes hafnium oxide, the dopant contained in the ferroelectric material film may include, for example, at least one of gadolinium (Gd), silicon (Si), zirconium (Zr), aluminum (Al), and yttrium (Y).

When the dopant is aluminum (Al), the ferroelectric material film may contain about 3 to about 8 at % (atomic %) of aluminum. In this connection, a content of the dopant may be a content of aluminum based on a sum of hafnium and aluminum.

When the dopant is silicon (Si), the ferroelectric material film may contain about 2 to about 10 at % of silicon. When the dopant is yttrium (Y), the ferroelectric material film may contain about 2 to about 10 at % yttrium. When the dopant is gadolinium (Gd), the ferroelectric material film may contain about 1 to about 7 at % gadolinium. When the dopant is zirconium (Zr), the ferroelectric material film may contain about 50 to about 80 at % zirconium.

The paraelectric material film may have paraelectric properties. The paraelectric material film may include, for example, at least one of silicon oxide and metal oxide having a high dielectric constant. Although the metal oxide contained in the paraelectric material film may include, for example, at least one of hafnium oxide, zirconium oxide and aluminum oxide. However, the present disclosure is not limited thereto.

The ferroelectric material film and the paraelectric material film may include the same material. The ferroelectric material film may have ferroelectric properties, but the paraelectric material film may not have the ferroelectric properties. For example, when each of the ferroelectric material film and the paraelectric material film includes hafnium oxide or hafnium zirconium oxide, a crystal structure of hafnium oxide contained in the ferroelectric material film is different from a crystal structure of hafnium oxide contained in the paraelectric material film. For example, the ferroelectric material film may include a crystal grain having an orthorhombic crystal system.

The ferroelectric material film may have a thickness configured to exhibit ferroelectric properties. Although the thickness of the ferroelectric material film may be, for example, in a range of about 0.5 nanometers (nm) to about 10 nm, the present disclosure is not limited thereto. Because a critical thickness for exhibiting the ferroelectric properties may vary based on a type of the ferroelectric material, the thickness of the ferroelectric material film may vary accordingly as a function of the type of the ferroelectric material.

In one example, the gate insulating film GI may include one ferroelectric material film. In another example, the gate insulating film GI may include a plurality of ferroelectric material films spaced apart from each other. The gate insulating film GI may have a multilayer structure in which a plurality of ferroelectric material films and a plurality of paraelectric material films are alternately stacked on top of each other.

A gate capping pattern GE_CAP may be disposed on the gate electrode GE. Contrary to what is shown, the gate capping pattern GE_CAP may not be disposed on the gate electrode GE.

Referring to FIG. 4, in some embodiments, the transistor TR may include a nanosheet NS, the gate electrode GE surrounding the nanosheet NS, and the gate insulating film GI between the nanosheet NS and the gate electrode GE.

The nanosheet NS may be disposed on a lower fin-type pattern BAF. The nanosheet NS may be spaced from the lower fin-type pattern BAF in a direction from the second surface 10b to the first surface 10a of the substrate 10 (i.e., the vertical direction). The nanosheet NS may include a plurality of nanosheets NS.

Each of the lower fin-type pattern BAF and the nano-sheet NS may include, for example, silicon or germanium which is an elemental semiconductor material. Each of the lower fin-type pattern BAF and the nano-sheet NS may include a compound semiconductor, for example, a group IV-IV compound semiconductor or a group III-V compound semiconductor. The lower fin-type pattern BAF and the nano sheet NS may include the same material or different materials.

Referring again to FIG. 1 and FIG. 2, the through-via 110 may extend through the substrate 10 and the first interlayer insulating film 100. An upper surface 110US of the through-via 110 is disposed on top of an upper surface 100US of the first interlayer insulating film 100. The upper surface 110US of the through-via 110 may be disposed between an upper surface of the second interlayer insulating film 200 and a lower surface of the second interlayer insulating film 200 (that is, the upper surface 100US of the first interlayer insulating film 100).

The through-via 110 may not contact the second interlayer insulating film 200.

In a direction from the second surface 10b of the substrate 10 toward the first surface 10a thereof, a depth of the through-via 110 may be smaller than a depth of the contact 120. A width of the through-via 110, in a direction parallel to the upper surface 10a of the substrate 10, may be larger than a width of the contact 120. The through-via 110 may be embodied as a through silicon via (TSV).

The through-via 110 may include a via barrier layer 112 and a via filling layer 114.

The via filling layer 114 may be formed to extend through the substrate 10 and the first interlayer insulating film 100. For example, the via filling layer 114 may include at least one of Cu, copper tin (CuSn), copper magnesium (CuMg), copper nickel (CuNi), copper zinc (CuZn), copper palladium (CuPd), copper gold (CuAu), copper rhenium (CuRe), copper tungsten (CuW), W, W alloy, titanium (Ti), titanium nitride (TiN), tantalum (Ta), and/or tantalum nitride (TaN).

The via filling layer 114 may include a material different from that of the contact 120. For example, the via filling layer 114 may include Cu, and the contact 120 may include W.

The via barrier layer 112 may surround a side surface of the via filling layer 114. For example, the via barrier layer 112 may include at least one of W, WN, WC, Ti, TiN, Ta, TaN, Ru, Co, Mn, WN, Ni, and NiB. However, embodiments of the present disclosure are not limited thereto. The term “surround” (or “surrounds,” or like terms), as may be used herein, is intended to broadly refer to an element, structure or layer that extends around, envelops, encircles, or encloses another element, structure or layer on all sides, although breaks or gaps may also be present. Thus, for example, a material layer having voids or gaps therein may still “surround” another layer which it encircles.

The via insulating layer 102 may be disposed on a side surface of the through-via 110. The via insulating layer 102 may surround (i.e., extend around) a side surface of the through-via 110. The via insulating layer 102 may extend along the side surface of the through-via 110. The via barrier layer 112 may be disposed between the via insulating layer 102 and the via filling layer 114. The via insulating layer 102 may extend along the via barrier layer 112. The via insulating layer 102 may include an insulating material film such as, for example, an oxide film, a nitride film, a carbonization film, a polymer, or a combination thereof. However, embodiments of the present disclosure are not limited thereto.

The second interlayer insulating film 200 may be disposed on the first interlayer insulating film 100. The second interlayer insulating film 200 is in contact with the first interlayer insulating film 100. The second interlayer insulating film 200 contacts the upper surface 100US of the first interlayer insulating film 100. The second interlayer insulating film 200 may include a different material than that of the first interlayer insulating film 100.

The second interlayer insulating film 200 may include a low dielectric constant (low-k) material. The low-k material may have a lower dielectric constant than that of silicon oxide. The low-k material may be, for example, silicon oxide with moderately high carbon and hydrogen contents, or for example, SiCOH. The carbon may be contained in the insulating material such that the dielectric constant of the insulating material may be lowered. However, to further lower the dielectric constant of the insulating material, the insulating material may contain pores, such as gas-filled or air-filled cavities, within the insulating material.

The low dielectric constant material may include, for example, fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), TOSZ (Tonen SilaZen), FSG (fluoride silicate glass), polyimide nanofoams such as polypropylene oxide, CDO (carbon doped silicon oxide), OSG (organo-silicate glass), SiLK, amorphous fluorinated carbon, silica aerogels, silica xerogels, mesoporous silica, or combinations thereof. However, the spirit of the present disclosure is not limited thereto.

The first lower wiring pattern 210 and the second lower wiring pattern 220 may be disposed within the second interlayer insulating film 200. A portion of each of the first lower wiring pattern 210 and the second lower wiring pattern 220 may extend into the first interlayer insulating film 100. A vertical level of each of a portion of a bottom surface of the first lower wiring pattern 210 and a bottom surface of the second lower wiring pattern 220 may be lower than a vertical level of the upper surface 100US of the first interlayer insulating film 100, relative to the upper surface 10a of the substrate 10 as a reference layer. A vertical level of each of an upper surface of the first lower wiring pattern 210 and an upper surface of the second lower wiring pattern 220 may be higher than a vertical level of each of the upper surface of the through-via 110 and the upper surface of the contact 120, relative to the upper surface 10a of the substrate 10.

The first lower wiring pattern 210 may be disposed on the through-via 110. The first lower wiring pattern 210 may be electrically connected to the through-via 110. The first lower wiring pattern 210 may extend through the second interlayer insulating film 200 so as to contact the upper surface 110US of the through-via 110.

The first lower wiring pattern 210 may surround a portion of a top portion of the through-via 110. A vertical level of the lowermost surface of the first lower wiring pattern 210 may be lower than a vertical level of the upper surface 110US of the through-via 110.

The second lower wiring pattern 220 may be disposed on the contact 120. The second lower wiring pattern 220 may be electrically connected to the contact 120. The second lower wiring pattern 220 may extend through the second interlayer insulating film 200 so as to contact an upper surface 120US of the contact 120.

A vertical level of the upper surface 120US of the contact 120 may be lower than a vertical level of the upper surface 100US of the first interlayer insulating film 100, relative to the upper surface 10a of the substrate 10 as a reference layer. The vertical level of the upper surface 120US of the contact 120 may be lower than a vertical level of the upper surface 110US of the through-via 110, relative to the upper surface 10a of the substrate 10.

In some embodiments, a vertical level of the upper surface 102US of the via insulating layer 102 may be higher than a vertical level of the upper surface 100US of the first interlayer insulating film 100, relative to the upper surface 10a of the substrate 10. The vertical level of the upper surface 102US of the via insulating layer 102 may be higher than a vertical level of the upper surface 120US of the contact 120, relative to the upper surface 10a of the substrate 10.

Each of the first lower wiring pattern 210 and the second lower wiring pattern 220 may include a first wiring barrier layer 212 and a first wiring filling layer 214. The first wiring filling layer 214 may be disposed on the first wiring barrier layer 212. The first wiring barrier layer 212 of the first lower wiring pattern 210 may extend along the upper surface 102US and at least a portion of a side surface of the via insulating layer 102 and the upper surface 110US of the through-via 110.

For example, the first wiring barrier layer 212 may extend along a sidewall and a bottom surface of the first wiring filling layer 214 and may not cover an upper surface of the first wiring filling layer 214 so as to be exposed. The term “exposed” may be used herein to describe relationships between elements and/or with reference to intermediate processes in fabricating an integrated circuit device, but may not require exposure of a particular element in the completed device. Likewise, the term “not exposed” may be used to described relationships between elements and/or with reference to intermediate processes in fabricating an integrated circuit device, but may not require a particular element to be unexposed in the completed device. In another example, the first wiring barrier layer 212 may not be disposed on the sidewall of the first wiring filling layer 214. In still another example, the first wiring barrier layer 212 may not be disposed on the bottom surface of the first wiring filling layer 214.

The first wiring barrier layer 212 may include at least one of a metal, conductive metal nitride, conductive metal carbide, conductive metal oxide, conductive metal carbonitride, and two-dimensional (2D) material, although embodiments are not limited thereto. For example, the first wiring barrier layer 212 may include at least one of Ta, TaN, Ti, TiN, TiSiN, Ru, Co, Ni, NiB, W, WN, WCN, Zr, ZrN, V, VN, Nb, NbN, Pt, Ir, Rh, Mo, and/or the two-dimensional material.

The two-dimensional material (2D material) may include a two-dimensional allotrope or a two-dimensional compound. For example, the 2D material may include at least one of graphene, boron nitride (BN), molybdenum disulfide (MoS₂), molybdenum diselenide (MoSe₂), tungsten diselenide (WSe₂), tungsten disulfide (WS₂), and/or tantalum disulfide. However, the present disclosure is not limited thereto. In other words, the above-described two-dimensional materials are listed only by way of example. The two-dimensional material that may be included in the semiconductor memory device of the present disclosure is not limited to the above-described materials.

The first wiring filling layer 214 may include a metal or a conductive compound including a metal. The first wiring filling layer 214 may include, for example, at least one of Al, Cu, W, Co, Ru, Ag, Au, Mn, Mo, Rh, Ir, RuAl, NiAl, NbB₂, MoB₂, TaB₂, V₂AlC and/or CrAlC. When the first wiring filling layer 214 includes Cu, the first wiring filling layer 214 may include, for example, C, Ag, Co, Ta In, Sn, Zn, Mn, Ti, Mg, Cr, Ge, Sr, Pt, Mg, Al, Zr, etc.

An etch stop film 250 may be disposed between the second interlayer insulating film 200 and the third interlayer insulating film 300. The etch stop film 250 may be disposed on the second interlayer insulating film 200, the first lower wiring pattern 210, and the second lower wiring pattern 220. The etch stop film 250 may include a material having an etch selectivity with respect to a material of the second interlayer insulating film 200.

The etch stop film 250 may include at least one of, for example, silicon nitride (SiN), silicon oxynitride (SiON), silicon oxycarbonitride (SiOCN), silicon boronitride (SiBN), silicon oxyboronitride (SiOBN), silicon carbonitride (SiCN), silicon oxycarbide (SiOC), aluminum oxide (AlO), aluminum nitride (AlN), aluminum oxycarbide (AlOC), and/or combinations thereof. The etch stop film 250 may be a single film or a multi-layer film.

The third interlayer insulating film 300 may be disposed on the second interlayer insulating film 200. For example, the third interlayer insulating film 300 may include at least one of silicon oxide, silicon nitride, silicon oxynitride, and a low dielectric constant material.

The first upper wiring pattern 310 may be disposed within the third interlayer insulating film 300. The first upper wiring pattern 310 may be disposed on the first lower wiring pattern 210. The first upper wiring pattern 310 may be electrically connected to the first lower wiring pattern 210. The first upper wiring pattern 310 may extend through the third interlayer insulating film 300 and the etch stop film 250 so as to contact the first lower wiring pattern 210.

The second upper wiring pattern 320 may be disposed on the second lower wiring pattern 220. The second upper wiring pattern 320 may be electrically connected to the second lower wiring pattern 220. The second upper wiring pattern 320 may extend through the third interlayer insulating film 300 and the etch stop film 250 so as to contact the second lower wiring pattern 220.

Each of the first upper wiring pattern 310 and the second upper wiring pattern 320 may include a second wiring barrier layer 312 and a second wiring filling layer 314. The second wiring filling layer 314 may be disposed on the second wiring barrier layer 312. For example, the second wiring barrier layer 312 may extend along a sidewall and a bottom surface of the second wiring filling layer 314 and may not cover an upper surface of the second wiring filling layer 314 so that the upper surface of the second wiring filling layer 314 is exposed. In another example, the second wiring barrier layer 312 may not be disposed on the sidewall of the second wiring filling layer 314. In still another example, the second wiring barrier layer 312 may not be disposed on the bottom surface of the second wiring filling layer 314.

The second wiring barrier layer 312 may include at least one of a metal, conductive metal nitride, conductive metal carbide, conductive metal oxide, conductive metal carbonitride, and the two-dimensional material. The second wiring filling layer 314 may include a metal or a conductive compound including a metal.

The first upper wiring pattern 310 may include a first via portion 310V and a first line portion 310L. The first via portion 310V may electrically connect the first lower wiring pattern 210 and the first line portion 310L to each other. The second upper wiring pattern 320 may include a second via portion 320V and a second line portion 320L. The second via portion 320V may electrically connect the second lower wiring pattern 220 and the second line portion 320L to each other.

The semiconductor device according to some embodiments may include the through-via 110, and each of the second interlayer insulating film 200 and the third interlayer insulating film 300 includes the low dielectric constant material. Therefore, a parasitic capacitance between the wiring patterns (for example, the first lower wiring pattern 210 and the second lower wiring pattern 220) may be reduced and thus resistive-capacitive (RC) delay may be reduced.

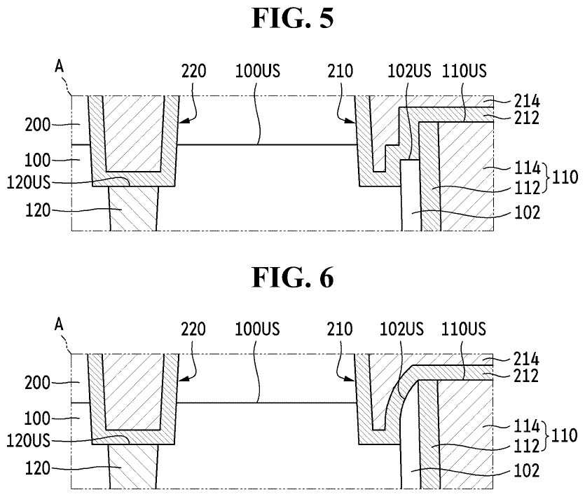

FIG. 5 and FIG. 6 are enlarged views of the portion A shown in FIG. 1. For convenience of description, following description focuses on differences thereof from the descriptions as set forth above using FIG. 1 to FIG. 4.

Referring to FIG. 5, in a semiconductor device according to some embodiments, a vertical level of the upper surface 102US of the via insulating layer 102 may be lower than a vertical level of the upper surface 110US of the through-via 110, relative to the upper surface 10a of the substrate 10. The upper surface 102US of the via insulating layer 102 and the upper surface 110US of the through-via 110 may define a step. The via insulating layer 102 may not cover a side surface of the via barrier layer 112 so as to be exposed.

The first wiring barrier layer 212 of the first lower wiring pattern 210 may extend along the upper surface 102US and a side surface of the via insulating layer 102, a side surface and upper surface of the via barrier layer 112, and the upper surface 110US of the through-via 110.

Referring to FIG. 6, the upper surface 102US of the via insulating layer 102 may be rounded. The upper surface 102US of the via insulating layer 102 may be convex toward the first lower wiring pattern 210. The first wiring barrier layer 212 of the first lower wiring pattern 210 may extend along the upper surface 102US of the via barrier layer 112.

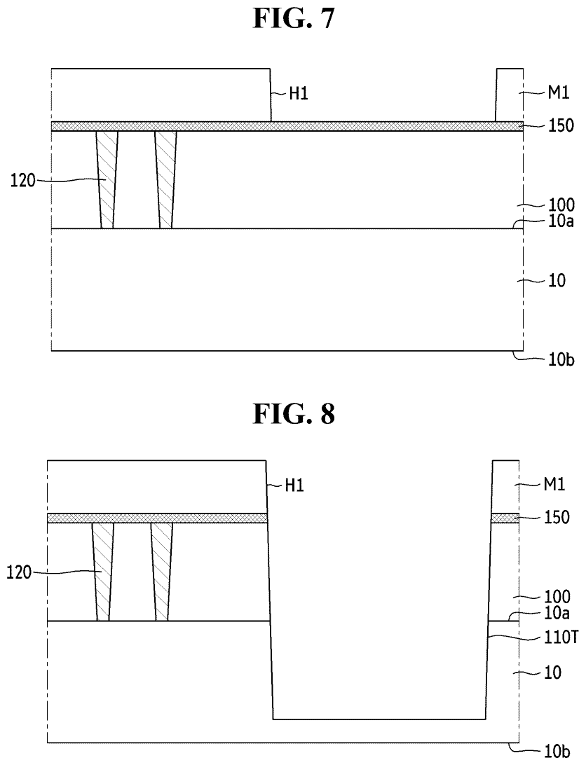

FIGS. 7 to 15 are schematic cross-sectional views illustrating intermediate processes in an example method for manufacturing a semiconductor device according to some embodiments. For convenience of description, the following description focuses on differences thereof from the descriptions as set forth above using FIGS. 1 to 6.

Referring to FIG. 7, the first interlayer insulating film 100 may be formed on the first surface 10a of the substrate 10. The contact 120 may be formed within the first interlayer insulating film 100.

A first etch stop film 150 is formed on the first interlayer insulating film 100. The first etch stop film 150 may cover the contact 120.

The first etch stop film 150 may include at least one of, for example, silicon nitride (SiN), silicon oxynitride (SiON), silicon oxycarbonitride (SiOCN), silicon boronitride (SiBN), silicon oxyboronitride (SiOBN), silicon carbonitride (SiCN), silicon oxycarbide (SiOC), aluminum oxide (AlO), aluminum nitride (AlN), aluminum oxycarbide (AlOC), and combinations thereof. The first etch stop film 150 may be a single film or a multi-layer film.

A first mask pattern M1 is formed on the first etch stop film 150. The first mask pattern M1 may include a first hole (i.e., opening) H1, which exposes a portion of an upper surface of the first etch stop film 150. The first mask pattern M1 may be formed on the first etch stop film 150 in an area where the contact 120 is formed. The first hole H1 may expose a portion of the upper surface of the first etch stop film 150 in an area where the contact 120 is not formed; that is, the first hole H1 may not overlap the contact 120 in the vertical direction. The term “overlap” (or “overlapping,” or like terms), as may be used herein, is intended to broadly refer to a first element that intersects with at least a portion of a second element in the vertical direction, but does not require that the first and second elements be completely aligned with one another in a horizontal plane (i.e., parallel to the upper surface 10a of the substrate 10.

The first mask pattern M1 may include photoresist. For example, a photoresist film may be applied on the first etch stop film 150, and the photoresist film may be patterned through an exposure process and a development process to form the first mask pattern M1 including the first hole H1.

Referring to FIG. 8, using the first mask pattern M1 as an etch mask, a portion of each of the first etch stop film 150, the first interlayer insulating film 100, and the substrate 10 is etched, thereby forming a via trench 110T. The via trench 110T may be formed at a location spaced apart from the contact 120. The via trench 110T may extend through a portion of each of the first etch stop film 150, the first interlayer insulating film 100, and the substrate 10. A bottom surface of the via trench 110T may be disposed between the first surface 10a of the substrate 10 and the second surface 10b of the substrate 10.

Subsequently, the first mask pattern M1 is removed, for example through ashing and stripping processes.

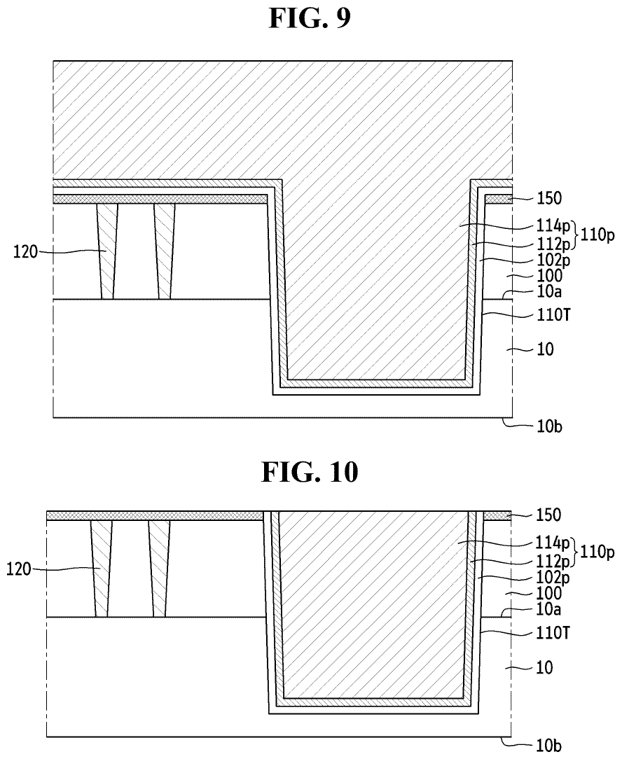

Referring to FIG. 9, a pre-via insulating layer 102p may be formed on the first etch stop film 150 and the via trench 110T. The pre-via insulating layer 102p may extend along the upper surface of the first etch stop film 150 and the via trench 110T. The pre-via insulating layer 102p may extend along a sidewall and a bottom surface of the via trench 110T.

A pre-via barrier layer 112p may be formed on the pre-via insulating layer 102p. The pre-via barrier layer 112p may be formed along the pre-via insulating layer 102p. A pre-via filling layer 114p may be formed on the pre-via barrier layer 112p. The pre-via filling layer 114p may cover the pre-via barrier layer 112p. The pre-via filling layer 114p may at least partially fill the via trench 110T. Accordingly, the pre-through-via 110p filling the via trench 110T may be formed on the pre-via insulating layer 102p. The pre-through-via 110p may include the pre-via barrier layer 112p and the pre-via filling layer 114p.

Referring to FIG. 10, a CMP (chemical mechanical polishing) process may be performed on the pre-via filling layer 114p, the pre-via barrier layer 112p, and the pre-via insulating layer 102p using the first etch stop film 150 as a stopper. Accordingly, the upper surface of the first etch stop film 150 may be exposed. The pre-via insulating layer 102p, the pre-via barrier layer 112p, and the pre-via filling layer 114p that fill the via trench 110T may remain. The pre-via insulating layer 102p, the pre-via barrier layer 112p, the pre-via filling layer 114p and the first etch stop film 150 may be coplanar with each other. The first etch stop film 150 may not cover an upper surface of the pre-through-via 110p that fills the -via trench 110T and an upper surface of the pre-via insulating layer 102p that fills the via trench 110T.

At this time, a portion of the first etch stop film 150 may be removed. For example, a thickness of the first etch stop film 150 in FIG. 9 may be smaller than a thickness of the first etch stop film 150 in FIG. 8. The first etch stop film 150 may be a film that will be removed later, and may have a thickness optimized (minimum thickness) for removing the first etch stop film 150.

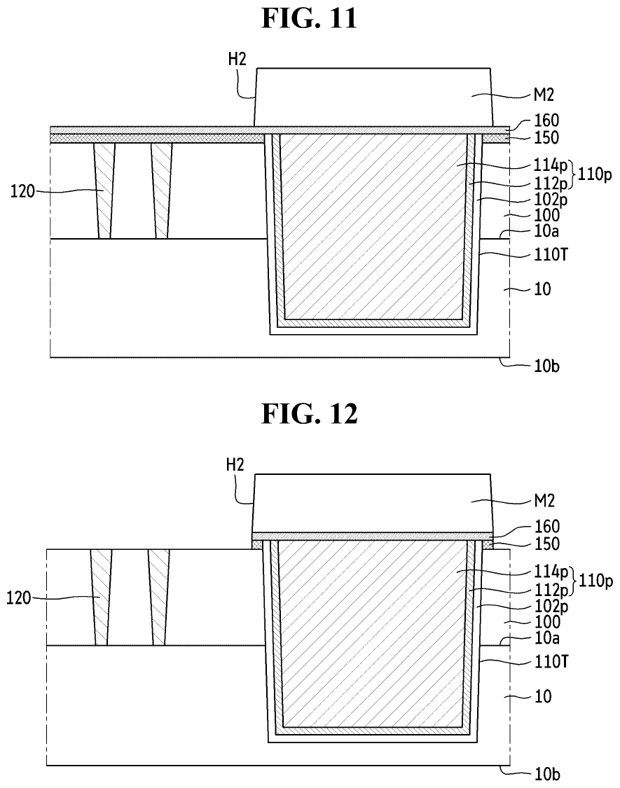

Referring to FIG. 11, a second etch stop film 160 is formed on the first etch stop film 150, the pre-through-via 110p, and the pre-via insulating layer 102p. The second etch stop film 160 covers the pre-through-via 110p and the pre-via insulating layer 102p.

The second etch stop film 160 may include at least one of, for example, silicon nitride (SiN), silicon oxynitride (SiON), silicon oxycarbonitride (SiOCN), silicon boronitride (SiBN), silicon oxyboronitride (SiOBN), silicon carbonitride (SiCN), silicon oxycarbide (SiOC), aluminum oxide (AlO), aluminum nitride (AlN), aluminum oxycarbide (AlOC), and/or combinations thereof. The second etch stop film 160 may be a single film or a multi-film.

The second etch stop film 160 may include a different material than that of the first etch stop film 150. For example, the first etch stop film 150 may include silicon nitride (SiN), and the second etch stop film 160 may include silicon carbonitride (SiCN).

The second etch stop film 160 may be a film that will be removed later, and may have a thickness optimized (minimum thickness) for removing the second etch stop film 160. For example, the thickness of the second etch stop film 160 may be smaller than the thickness of the first etch stop film 150.

Subsequently, a second mask pattern M2 is formed on a portion of the second etch stop film 160. The second mask pattern M2 may include a second hole (i.e., opening) H2, which exposes a portion of an upper surface of the second etch stop film 160. The second mask pattern M2 may be formed on the second etch stop film 160 in an area where the pre-through-via 110p and the pre-via insulating layer 102p are formed. The second hole H2 may expose the second etch stop film 160 in an area where the pre-through-via 110p and the pre-via insulating layer 102p are not formed.

For example, a width (a width of a bottom surface) of the second mask pattern M2 in the horizontal direction, parallel to the upper surface 10a of the substrate 10, may be larger than a width (a width of a top surface) of the through-via trench 110T. The second hole H2 may expose the portion of the upper surface of the second etch stop film 160 in the area where the pre-through-via 110p and the pre-via insulating layer 102p are not formed.

The second mask pattern M2 may include photoresist. For example, a photoresist film may be applied on the second mask pattern M2, and the photoresist film may be patterned through an exposure process and a development process to form the second mask pattern M2 including the second hole H2.

Referring to FIG. 12, the first etch stop film 150 and the second etch stop film 160 are etched using the second mask pattern M2 as an etch mask, thereby exposing a portion of the upper surface of the first interlayer insulating film 100. The upper surface of the contact 120 may also be exposed. The second etch stop film 160 may cover the pre-through-via 110p and the pre-via insulating layer 102p, and may not cover the first interlayer insulating film 100 in the area in which the contact 120 is formed.

The second etch stop film 160 may be disposed between the pre-through-via 110p and the second mask pattern M2, so that the pre-through-via 110p and the second mask pattern M2 may be spaced apart from each other.

A width in the horizontal direction of a bottom of the second mask pattern M2 may be larger than a width in the horizontal direction of a top of the via trench 110T. That is, the first etch stop film 150 may remain between the second mask pattern M2 and the first interlayer insulating film 100. The first etch stop film 150 may remain on a side surface of the pre-via insulating layer 102p. The second etch stop film 160 may remain on the first etch stop film 150, the pre-via insulating layer 102p, and the pre-through-via 110p.

Subsequently, the second mask pattern M2 is removed through ashing and stripping processes.

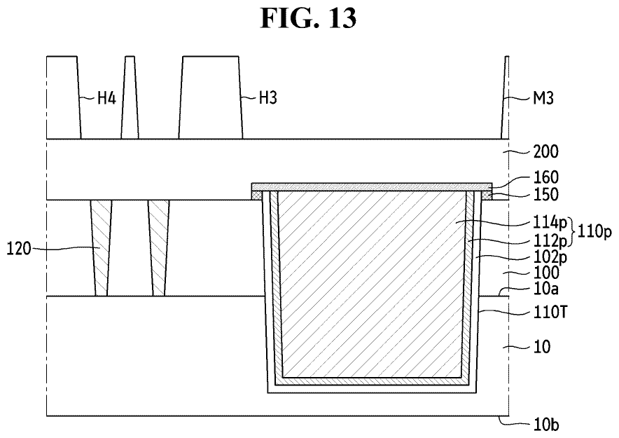

Referring to FIG. 13, the second interlayer insulating film 200 is formed on the first interlayer insulating film 100 and the second etch stop film 160. The second interlayer insulating film 200 may cover the first interlayer insulating film 100, the contact 120, the first etch stop film 150, and the second etch stop film 160.

Subsequently, a third mask pattern M3 is formed on the second interlayer insulating film 200. The third mask pattern M3 may include a third hole (i.e., opening) H3 and a fourth hole (i.e., opening) H4. Each of the third hole H3 and the fourth hole H4 may expose a portion of an upper surface of the second interlayer insulating film. The third hole H3 may overlap the second etch stop film 160 in the vertical direction (i.e., in a direction from the second surface 10b to the first surface 10a of the substrate 10). The fourth hole H4 may overlap at least a portion of the contact 120 in the vertical direction (i.e., from the second surface 10b to the first surface 10a of the substrate 10).

The third mask pattern M3 may include photoresist. For example, a photoresist film is applied on the second interlayer insulating film 200, and the photoresist film is patterned through an exposure process and a development process to form the third mask pattern M3 including the third hole H3 and the fourth hole H4.

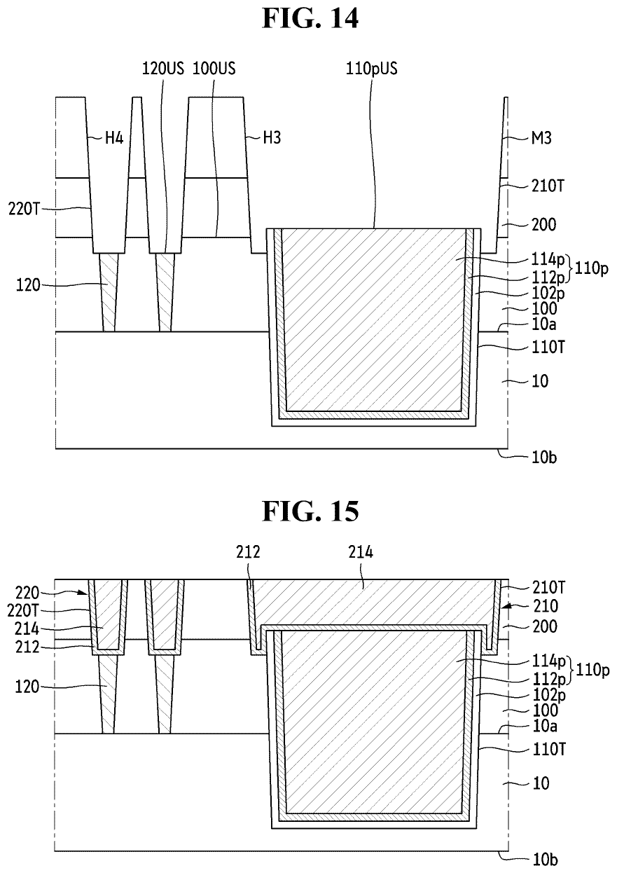

Referring to FIG. 14, a first wiring trench 210T and a second wiring trench 220T are formed using the third mask pattern M3.

Using the third mask pattern M3 as an etch mask, a portion of each of the second interlayer insulating film 200, the second etch stop film 160, the first etch stop film 150, and the first interlayer insulating film 100 are etched, thereby forming the first wiring trench 210T. The first wiring trench 210T may expose the upper surface of the pre-through-via 110p and the upper surface of the pre-via insulating layer 102p. A width in the horizontal direction of the first wiring trench 210T may be larger than a width in the horizontal direction of the via trench 110T. In the process of forming the first wiring trench 210T, both the first etch stop film 150 and the second etch stop film 160 may be removed. Accordingly, the etch stop film (for example, the first etch stop film 150 and/or the second etch stop film 160) may not be disposed between the second interlayer insulating film 200 and the first interlayer insulating film 100, and the second interlayer insulating film 200 and the first interlayer insulating film 100 may contact each other.

Each of the pre-through-via 110p and the pre-via insulating layer 102p may have a shape that protrudes (i.e., extends upwardly) from a bottom surface of the first wiring trench 210T. That is, a vertical level of an upper surface 110pUS of the pre-through-via 110p may be higher than a vertical level of a bottom surface of the first wiring trench 210T, relative to the upper surface 10a of the substrate 10 as a reference layer. The first wiring trench 210T may expose a top portion of each of the pre-through-via 110p and the pre-via insulating layer 102p. A side surface of the top portion of the pre-via insulating layer 102p may be exposed through the first wiring trench 210T.

For example, in the process of forming the first wiring trench 210T and the second wiring trench 220T, a portion of the pre-via insulating layer 102p may be etched. A vertical level of the upper surface of pre-via insulating layer 102p may be lower than a vertical level of the upper surface 110pUS of the pre-through-via 110p, relative to the upper surface 10a of the substrate 10. For example, as shown in FIG. 5, a step may be formed between the upper surface 102US of the pre-via insulating film 102p and the upper surface 110US of the through-via 110. For example, as shown in FIG. 6, the upper surface 102US of the pre-via insulating film 102p may be rounded. Using the third mask pattern M3 as an etching mask, a portion of each of the second interlayer insulating film 200 and the first interlayer insulating film 100 is etched to form the second wiring trench 220T. The second wiring trench 220T may expose the upper surface of the contact 120.

In the process of forming the first wiring trench 210T and the second wiring trench 220T, the first interlayer insulating film 100 and the contact 120 may be over-etched. A vertical level of each of a bottom surface of the first wiring trench 210T and a bottom surface of the second wiring trench 220T may be lower than a vertical level of the upper surface 100US of the first interlayer insulating film 100, relative to the upper surface 10a of the substrate 10. A vertical level of the upper surface 120US of the contact 120 may be lower than a vertical level of the upper surface 100US of the first interlayer insulating film 100, relative to the upper surface 10a of the substrate 10.

Subsequently, the third mask pattern M3 may be removed.

Referring to FIG. 15, the first wiring barrier layer 212 may be formed along the first wiring trench 210T and the second wiring trench 220T. The first wiring barrier layer 212 may extend along a bottom surface and a sidewall of the first wiring trench 210T, and the pre-through-via 110p and the pre-via insulating layer 102p exposed through the first wiring trench 210T. The first wiring barrier layer 212 may extend along a bottom surface and a sidewall of the second wiring trench 220T.

The first wiring filling layer 214 may be formed on the first wiring barrier layer 212. The first wiring filling layer 214 may be formed on the first wiring barrier layer 212 so as to fill the first wiring trench 210T and the second wiring trench 220T. Accordingly, the first lower wiring pattern 210 and the second lower wiring pattern 220, each including the first wiring barrier layer 212 and the first wiring filling layer 214, may be formed.

Next, referring to FIG. 1, the etch stop film 250 may be formed on the second interlayer insulating film 200. The etch stop film 250 may cover the first lower wiring pattern 210 and the second lower wiring pattern 220.

Subsequently, the third interlayer insulating film 300 may be formed on the etch stop film 250. The first upper wiring pattern 310 and the second upper wiring pattern 320 may be formed within the third interlayer insulating film 300.

A planarization process may be performed on the second surface 10b of the substrate 10 so that a bottom surface (opposite the upper surface 110US) of the pre-through-via 110p is exposed. Accordingly, the via insulating layer 102 may be formed between the through-via 110 including the via barrier layer 112 and the via filling layer 114 and the substrate 10, and between the through-via 110 and the first interlayer insulating film 100. The via insulating layer 102, the via barrier layer 112, and the via filling layer 114 may be exposed to the second surface 10b of the substrate 10.

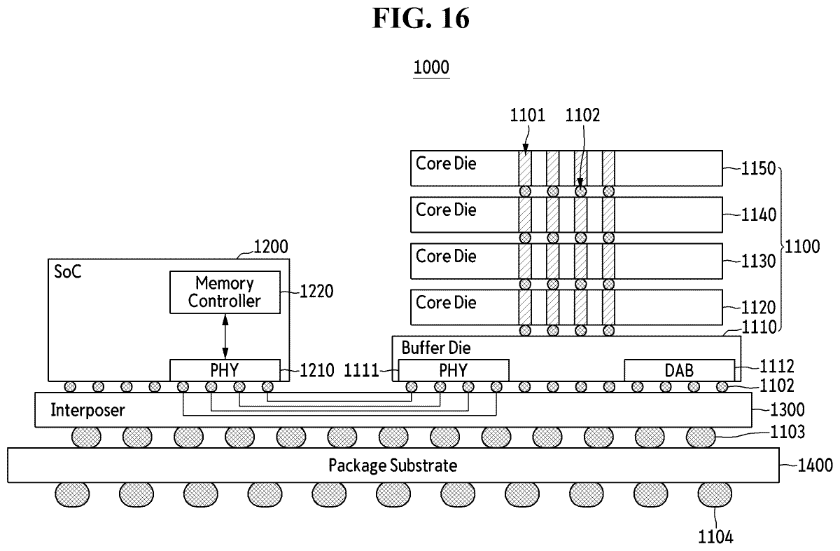

FIG. 16 is a diagram for illustrating a semiconductor package according to some embodiments.

Referring to FIG. 16, a semiconductor package 1000 may include a stack type memory device 1100, a system on chip (SoC) 1200, an interposer 1300, and a package substrate 1400. The stack type memory device 1100 may include a buffer die 1110 and core dies 1120, 1130, 1140 and 1150.

Each of the core dies 1120 to 1150 may include a memory cell array. Each of the core dies 1120 to 1150 may include the semiconductor device as described above with reference to FIGS. 1 to 15. TSV 1101 may correspond to the through-via 110 as described above with reference to FIGS. 1 to 15.

The buffer die 1110 may include a physical layer (PHY) 1111 and a direct access area (DAB) 1112. The physical layer 1111 may be electrically connected to a physical layer 1210 of the system on chip 1200 via the interposer 1300. The stack type memory device 1100 may receive signals from the system on chip 1200 via the physical layer 1111 or transmit signals to the system on chip 1200 via the physical layer 1111.

The direct access area 1112 may provide an access path for testing the stack type memory device 1100 without passing through the system on chip 1200. The direct access area 1112 may include conductive means (e.g., a port or a pin) that may communicate directly with an external test device. A test signal and data received through the direct access area 1112 may be transmitted to the core dies 1120 to 1150 via the TSVs 1101. For testing of the core dies 1120 to 1150, data read-out from the core dies 1120 to 1150 may be transmitted to a test device via the TSVs 1101 and the direct access area 1112. Accordingly, a direct access test of the core dies 1120 to 1150 may be performed.

The buffer die 1110 and the core dies 1120 to 1150 may be electrically connected to each other via the TSVs 1101 and conductive bumps (e.g., solder bumps) 1102. The buffer die 1110 may receive signals provided to each channel from the system on chip 1200 via the bumps 1102 allocated to each channel. For example, the bumps 1102 may be embodied as micro bumps.

The system on chip 1200 may execute applications supported by the semiconductor package 1000 using the stack type memory device 1100. For example, the system on chip 1200 may include at least one processor of CPU (Central Processing Unit), AP (Application Processor), GPU (Graphic Processing Unit), NPU (Neural Processing Unit), TPU (Tensor Processing Unit), VPU (Vision Processing Unit), ISP (Image Signal Processor), and DSP (Digital Signal Processor) to execute computing specialized therein.

The system on chip 1200 may include the physical layer 1210 and a memory controller 1220. The physical layer 1210 may include input/output circuits for transmitting and receiving signals to and from the physical layer 1111 of the stack type memory device 1100. The system on chip 1200 may provide various signals to the physical layer 1111 via the physical layer 1210. The signals provided to the physical layer 1111 may be transmitted to the core dies 1120 to 1150 via the interface circuits of the physical layer 1111 and the TSVs 1101.

The memory controller 1220 may control all operations of the stack type memory device 1100. The memory controller 1220 may transmit signals for controlling the stack type memory device 1100 to the stack type memory device 1100 via the physical layer 1210.

The interposer 1300 may connect the stack type memory device 1100 and the system on chip 1200 to each other. The interposer 1300 may be connected to the physical layer 1111 of the stack type memory device 1100 and the physical layer 1210 of the system on chip 1200 and may provide physical paths made of a conductive material. Accordingly, the stack type memory device 1100 and the system on chip 1200 may be stacked on the interposer 1300 and thus transmit and receive signals to and from each other via the interposer 1300.

Bumps (e.g., solder bumps) 1103 may be provided on (e.g., attached to) a top of the package substrate 1400. Solder balls 1104 may be provided on a bottom of the package substrate 1400. For example, the bumps 1103 may be embodied as flip-chip bumps. The interposer 1300 may be stacked on the package substrate 1400 via the bumps 1103. The semiconductor package 1000 may transmit and receive signals to and from other external packages or semiconductor devices via the solder balls 1104. For example, the package substrate 1400 may be embodied as a printed circuit board (PCB).

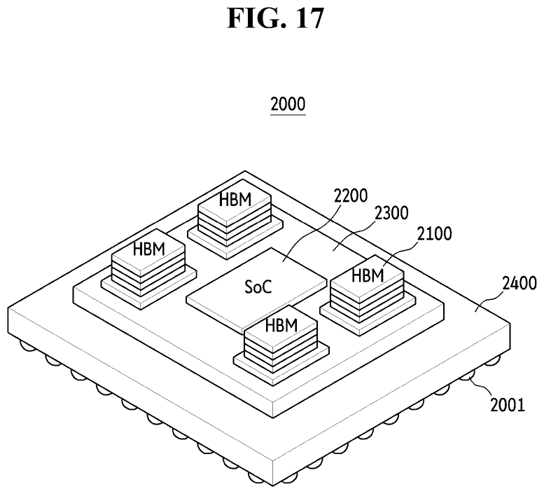

FIG. 17 is a diagram for illustrating an implementation example of a semiconductor package according to some embodiments.

Referring to FIG. 17, a semiconductor package 2000 may include a plurality of stack type memory devices 2100 and a system on chip SoC 2200. The stack type memory devices 2100 and the system on chip 2200 may be stacked on an interposer 2300. The interposer 2300 may be stacked on a package substrate 2400. The semiconductor package 2000 may transmit and receive signals to and from other external packages or semiconductor devices via solder balls 2001 provided on a bottom of the package substrate 2400.

Each of the stack type memory devices 2100 may be implemented based on a high-bandwidth memory (HBM) standard. However, the present disclosure is not limited thereto. Each of the stack type memory devices 2100 may be implemented based on a graphics double data rate (GDDR), hybrid memory cube (HMC), or Wide I/O standard. Each of the stack type memory devices 2100 may correspond to the stack type memory device 1100 of FIG. 16.

The system on chip 2200 may include at least one processor such as a CPU, an AP, a GPU, and an NPU and a plurality of memory controllers for controlling a plurality of stack type memory devices 2100. The system on chip 2200 may transmit and receive signals to and from each stack type memory device via each memory controller.

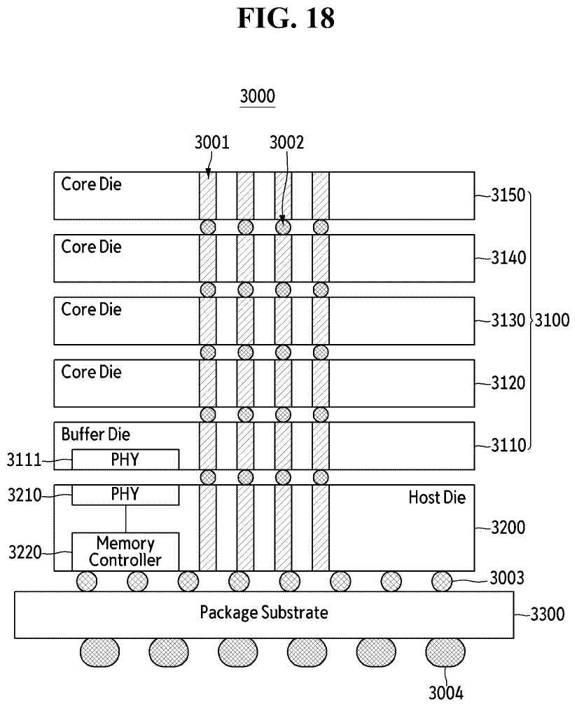

FIG. 18 is a diagram for illustrating a semiconductor package according to some embodiments.

Referring to FIG. 18, a semiconductor package 3000 may include a stack type memory device 3100, a host die 3200, and a package substrate 3300. The stack type memory device 3100 may include a buffer die 3110 and core dies 3120, 3130, 3140 and 3150. The buffer die 3110 includes a physical layer 3111 for communicating with the host die 3200, and each of the core dies 3120 to 3150 may include a memory cell array.

The host die 3200 may include a physical layer 3210 to communicate with the stack type memory device 3100 and a memory controller 3220 to control all operations of the stack type memory device 3100. Further, the host die 3200 may control all operations of the semiconductor package 3000 and may include a processor for executing applications supported by the semiconductor package 3000. For example, the host die 3200 may include at least one processor such as CPU, AP, GPU, and NPU.

The stack type memory device 3100 may be disposed on the host die 3200 based on TSVs 3001 and may be vertically stacked on the host die 3200. Accordingly, the buffer die 3110, the core dies 3120 to 3150, and the host die 3200 may be electrically connected to each other via the TSVs 3001 and bumps 3002 without an interposer. For example, the bumps 3002 may be embodied as micro bumps. The TSV 3001 may correspond to the through-via 110 as described above with reference to FIGS. 1 to 15.

Bumps 3003 may be provided on a top surface of the package substrate 3300, while solder balls 3004 may be provided on a bottom surface of the package substrate 3300. For example, the bumps 3003 may be embodied as flip-chip bumps. The host die 3200 may be stacked on the package substrate 3300 via the bumps 3003. The semiconductor package 3000 may transmit and receive signals to and from other external packages or semiconductor devices via the solder balls 3004.

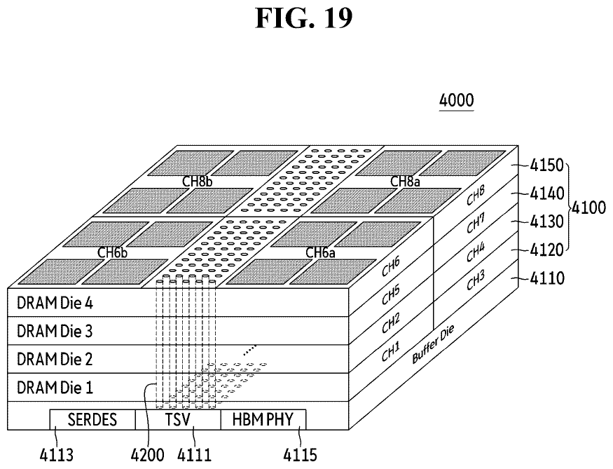

FIG. 19 is a diagram for illustrating a memory device according to some embodiments.

Referring to FIG. 19, a memory device 4000 may be an HBM including multiple channels CH1 to CH8 with independent interfaces. The memory device 4000 may include a plurality of dies. The dies may include a buffer die 4110 and at least one DRAM die 4100 stacked on the buffer die 4110. For example, a first DRAM die 4120 may include the first channel CH1 and the third channel CH3, a second DRAM die 4130 may include the second channel CH2 and the fourth channel CH4, a third DRAM die 4140 may include the fifth channel CH5 and the seventh channel CH7, and a fourth DRAM die 4150 may include the sixth channel CH6 and the eighth channel CH8.

The buffer die 4110 may communicate with an external CPU through conductive means, such as bumps or solder balls, formed on an outer surface of the memory device 4000. The buffer die 4110 may receive commands, addresses, and/or data from the CPU, and may provide the received commands, addresses, and data to at least one channel of the DRAM die 4100. Furthermore, the buffer die 4110 may provide data output from the at least one channel of the DRAM die 4100 to the CPU.

The memory device 4000 may include a plurality of through silicon vias (TSVs) 4200 extending through DRAM dies 4120 to 4150. When each of the channels CH1 to CH8 has a bandwidth of 128 bits, the TSVs 4200 may include components for data input and output of 1024 bits. Each of the channels CH1 to CH8 may be divided into left and right channels. In an example, in the fourth DRAM die 4150, the sixth channel CH6 may be divided into pseudo channels CH6a and CH6b, and the eighth channel CH8 may be divided into pseudo channels CH8a and CH8b. The TSVs 4200 may be disposed between the pseudo channels CH6a and CH6b of the sixth channel CH6, and between the pseudo channels CH8a and CH8b of the eighth channel CH8. The TSV 4200 may correspond to the through-via 110 as described above with reference to FIG. 1 to FIG. 15.

The buffer die 4110 may include a TSV area 4111, a serializer/deserializer (SERDES) area 4113, and a HBM physical layer interface, that is, a HBM PHY area 4115. The TSV area 4111 is an area where the TSV 4200 for communication with the at least one DRAM die 4100 is formed.

The SERDES area 4113 is an area that provides a SERDES interface of JEDEC (Joint Electron Device Engineering Council) standard as CPU processing throughput increases and demands for a memory bandwidth increase. The SERDES area 4113 may include a SERDES transmitter portion, a SERDES receiver portion, and a controller portion. The SERDES transmitter portion may include parallel-to-serial circuitry and a transmitter, and may receive parallel data streams and serialize the received parallel data streams. The SERDES receiver portion may include a receiver, an amplifier, an equalizer, a clock and data recovery (CDR) circuitry, and series-to-parallel circuitry and may receive a serial data stream and parallelize the received serial data stream. The controller portion may include an error detection circuit, an error correction circuit, and registers such as FIFO (First In First Out).

The HBM PHY area 4115 may include a physical or electrical layer and a logical layer provided for signals, frequency, timing, operation, detailed operating parameters, and functionality required for efficient communication between the CPU and the memory device 4000. The HBM PHY area 4115 may perform memory interfacing, such as selecting rows and columns corresponding to memory cells, writing data to the memory cells, or reading written data.

The HBM PHY area 4115 may support features of a HBM protocol of the JEDEC standard. In an example, the HBM PHY area 4115 may perform 64 bit-sized data communication with the CPU.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

1. A semiconductor device, comprising:
a substrate;
a first interlayer insulating film on the substrate;
a through-via extending through the substrate and the first interlayer insulating film;
a second interlayer insulating film on the first interlayer insulating film, wherein the second interlayer insulating film includes a low dielectric constant material and is in contact with an upper surface of the first interlayer insulating film; and
a first wiring pattern in the second interlayer insulating film and on the through-via.

2. The semiconductor device of claim 1, wherein a vertical level of an upper surface of the through-via is higher than a vertical level of the upper surface of the first interlayer insulating film, relative to an upper surface of the substrate.

3. The semiconductor device of claim 1, wherein the first wiring pattern extends through the first second interlayer insulating film so as to contact an upper surface of the through-via.

4. The semiconductor device of claim 1, wherein an upper surface of the through-via is between an upper surface of the second interlayer insulating film and a lower surface of the second interlayer insulating film.

5. The semiconductor device of claim 1, further comprising:
a third interlayer insulating film on the second interlayer insulating film; and
a second wiring pattern in the third interlayer insulating film and on the first wiring pattern.

6. The semiconductor device of claim 5, wherein the third interlayer insulating film includes a low dielectric constant material.

7. The semiconductor device of claim 5, further comprising an etch stop film between the second interlayer insulating film and the third interlayer insulating film.

8. A semiconductor device, comprising:
a substrate;
a circuit element on the substrate;
a contact on the substrate and electrically connected to the circuit element;
a first interlayer insulating film on the substrate and over the circuit element and the contact;
a through-via extending through the first interlayer insulating film and the substrate;
a second interlayer insulating film on the first interlayer insulating film, wherein the second interlayer insulating film includes a low dielectric constant material and is isolated from the through-via;
a first wiring pattern extending through the second interlayer insulating film so as to contact the through-via; and
a second wiring pattern extending through the second interlayer insulating film so as to contact the contact.

9. The semiconductor device of claim 8, wherein a vertical level of an upper surface of the through-via is higher than a vertical level of an upper surface of the first interlayer insulating film, relative to an upper surface of the substrate.

10. The semiconductor device of claim 8, wherein a vertical level of an upper surface of the through-via is higher than a vertical level of an upper surface of the contact, relative to an upper surface of the substrate.

11. The semiconductor device of claim 8, wherein the first interlayer insulating film is in contact with the second interlayer insulating film.

12. The semiconductor device of claim 8, wherein a vertical level of an upper surface of the contact is lower than a vertical level of an upper surface of the first interlayer insulating film, relative to an upper surface of the substrate.

13. The semiconductor device of claim 8, further comprising a via insulating layer on a side surface of the through-via,
wherein a vertical level of an upper surface of the via insulating layer is higher than a vertical level of an upper surface of the first interlayer insulating film, relative to an upper surface of the substrate.

14. The semiconductor device of claim 8, further comprising a via insulating layer on a side surface of the through-via,
wherein a vertical level of an upper surface of the via insulating layer is lower than a vertical level of an upper surface of the contact, relative to an upper surface of the substrate.

15. The semiconductor device of claim 8, wherein the contact includes a material different from a material of the through-via.

16. The semiconductor device of claim 8, wherein a vertical level of an upper surface of the first wiring pattern is higher than a vertical level of an upper surface of the through-via, relative to an upper surface of the substrate.

17. A method for manufacturing a semiconductor device, the method comprising:
forming a first interlayer insulating film on a substrate, and forming a contact in the first interlayer insulating film;
forming a pre-through-via extending through a portion of the substrate and the first interlayer insulating film;
forming a first etch stop film on the pre-through-via such that the first etch stop film does not overlap the first interlayer insulating film in a vertical direction perpendicular to an upper surface of the substrate so as to expose an area in which the contact is formed;
forming a second interlayer insulating film on the first etch stop film and the first interlayer insulating film;
forming a first wiring trench and a second wiring trench in the second interlayer insulating film, wherein forming the first wiring trench includes etching the second interlayer insulating film and the first etch stop film, wherein forming the second wiring trench includes etching the second interlayer insulating film; and
forming a first wiring pattern at least partially filling the first wiring trench and forming a second wiring pattern at least partially filling the second wiring trench.

18. The method of claim 17, wherein forming the pre-through-via includes:
forming a second etch stop film on the first interlayer insulating film;
forming a via trench extending through the portion of the substrate and the first interlayer insulating film; and
forming the pre-through-via in the via trench,
wherein forming the second etch stop film includes:
after forming the second etch stop film on the first etch stop film and the pre-through-via, removing a portion of the first etch stop film on the contact and removing a portion of the second etch stop film on the contact,
wherein forming the first wiring trench includes etching a portion of the second etch stop film on the through-via.

19. The method of claim 18, wherein forming the pre-through-via includes:
after forming the pre-through-via so as to at least partially fill the via trench and cover the first interlayer insulating film, planarizing the pre-through-via using the first etch stop film.

20. The method of claim 17, wherein the first interlayer insulating film includes a low dielectric constant material layer.
